(19) United States
(12) Patent Application Publication
(10) Pub. No.: US 2025/0372147 A1
(43) Pub. Date: Dec. 4, 2025

(54) READ CLOCK GENERATION FOR SYNCHRONOUS GRAPHICS RANDOM ACCESS MEMORY

(71) Applicant: Micron Technology, Inc., Boise, ID (US)

(72) Inventor: Kevin GAJERA, Munich (DE)

(21) Appl. No.: 19/191,093

(22) Filed: Apr. 28, 2025

Related U.S. Application Data
(60) Provisional application No. 63/652,494, filed on May 28, 2024.

(51) Int. Cl. G11C 11/4076; G11C 11/408

(52) U.S. Cl. CPC G11C 11/4076; G11C 11/4087

(57) ABSTRACT

In some implementations, a memory apparatus including a synchronous graphics random access memory (SGRAM) associated with a first clock signal having a first clock frequency may receive a command to initiate a read clock. The memory apparatus may generate read clock data based on one or more control parameters stored to a mode register and a second clock signal having a second clock frequency that is double the first clock frequency. The memory apparatus may output a read clock signal that is based on the read clock data, the read clock signal having a third clock frequency that is double the second clock frequency, wherein the read clock signal is associated with a memory access command for the SGRAM.

### CROSS-REFERENCE TO RELATED APPLICATION

This patent application claims priority to U.S. Provisional Patent Application No. 63/652,494, filed on May 28, 2024, entitled “READ CLOCK GENERATION FOR SYNCHRONOUS GRAPHICS RANDOM ACCESS MEMORY,” and assigned to the assignee hereof. The disclosure of the prior application is considered part of and is incorporated by reference into this patent application.

### TECHNICAL FIELD

The present disclosure generally relates to memory devices and, for example, read clock generation for synchronous graphics random access memory.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), synchronous graphics RAM (SGRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of read clock generation for synchronous graphics RAM (SGRAM).

FIG. 2 is a diagrammatic view of an example memory device that supports read clock generation for SGRAM.

FIG. 3 is a diagram illustrating an example of a system that supports read clock generation for SGRAM.

FIG. 4 is a diagram illustrating an example of a timing diagram that supports read clock generation for SGRAM.

FIG. 5 is a diagram illustrating an example of a timing diagram that supports read clock generation for SGRAM.

FIG. 6 is a flowchart of an example method associated with read clock generation for SGRAM.

### DETAILED DESCRIPTION

Some memory apparatuses, such as graphics double data rate (GDDR) memory systems, dynamic random access memory (DRAM) systems, and/or synchronous graphics random access memory (SGRAM) systems, among other examples, may communicate data at a relatively high transfer speed (e.g., a rate at which data is communicated between a memory apparatus and a host system). To facilitate increased data transfer speeds, such systems may communicate data using a higher clock speed (e.g., an increased clock frequency), relative to other systems. By increasing the clock speed of communicated data, a memory apparatus may communicate more data within a given time interval. However, an increased clock speed may also reduce the time window used to decode a data signal that includes the data. Reducing the time window to decode data signals may increase the likelihood of introducing errors into the data, such as errors due to misalignment between the data signal and a clock signal used to decode the data signal, and/or increased noise within the data signal, among other examples.

In some examples, a host system may provide a clock signal to the memory apparatus, and the host system may interpret received data signals from the memory apparatus using the provided clock signal (e.g., by using the clock signal to latch data from the data signal). To mitigate errors due to misalignment between the provided clock signal and the data signal, a host system may “train” the memory apparatus, for example by applying offsets or delays to the provided clock signal and/or the data signal. However, such training may not be able to account for variations in the data signal due to changes in temperature and/or changes in supply voltage, which may increase the likelihood of misalignment between the clock signal provided by the host system and the data signal provided by the memory apparatus.

Some implementations described herein enable a memory apparatus that includes an SGRAM apparatus to implement (e.g., generate and transmit) a read clock signal. In some cases, the memory apparatus may generate the read clock signal using one or more internal clock signals that are based on an external clock signal received from a host system. Such internal clock signal(s) may have a reduced frequency compared to the frequency of the external clock signal. For example, the memory apparatus may generate a base clock signal having a base frequency (e.g., a frequency of one quarter of the external clock frequency) and may generate an intermediate clock signal having an intermediate clock frequency that is double the base frequency.

The memory apparatus may include a read clock control component configured to generate read clock data. In some cases, the read clock control component may include one or more combinational circuits that generate the read clock data based on one or more control parameters (e.g., a swing parameter, a preamble parameter, and/or a synchronization parameter, among other examples). For example, a combinational circuit may include one or more logic circuits, such as gates and/or multiplexers, configured to output all, or a portion of, the read clock data based one or more inputs to the combinational circuit. The memory apparatus may provide the one or more control parameters to the one or more combinational circuits (e.g., as an input) to enable the one or more combinational circuits to generate the read clock data in accordance with the one or more control parameters.

The read clock control component may provide the read clock data to a read clock generator. The read clock generator may generate a read clock signal having a frequency that is equal to the external clock frequency (e.g., double the intermediate clock frequency, quadruple the base clock frequency). In some implementations, the read clock generator may include one or more serialization components that obtain all, or a portion of, the read clock data from the read clock control component. Additionally, a serialization component may obtain a clock signal, such as the intermediate clock signal. The serialization component may selectively output a single value at a time (e.g., a high value and/or a low value, a logic “1” and/or a logic “0”) based on the obtained clock signal.

The read clock generator may include one or more drivers configured to obtain an output signal of respective serialization components (e.g., as one or more inputs to the one or more drivers). In some implementations, the output of a driver may be based on the one or more inputs to the driver. For example, a driver may be configured to encode multiple (e.g., two) signal levels corresponding to the inputs into a single output signal level. In some implementations, the output of a driver may be one of multiple (e.g., 3) possible values, such as a value corresponding to a ternary digit. Such values may have a voltage level that is a percentage of a supply voltage of the memory apparatus. The one or more drivers may be configured to encode the output signals of the serialization components to provide the read clock signal, as described in greater detail elsewhere herein.

By the memory apparatus generating and/or providing a read clock signal, misalignments due to temperature and/or supply voltages may be reduced. For example, if the memory apparatus receives a read command, then the memory apparatus may transmit data associated with the read command and may transmit a read clock signal along with the data. The host system may use the read clock signal to interpret data transmitted by the memory system. Because the read clock signal may experience similar variations (e.g., variations due to temperature changes and/or supply voltage changes) as the data signal, the likelihood of the misalignment between the read clock signal and the data signal may be reduced, which may in turn improve the ability of the host system to interpret the data signal.

Additionally, by enabling the read clock control component to provide the read clock data to the read clock generator, the read clock generator may generate the read clock signal using the intermediate clock frequency. Such an implementation may improve performance of the memory apparatus. For example, if a memory apparatus uses the base clock signal to generate the read clock signal, then the memory apparatus may include additional signal processing stages (e.g., additional serialization components or other signal processing circuitry) to generate the read clock signal. Such additional stages may cause added delay associated with generating the read clock signal, which may in turn increase latency (e.g., latency for providing data from an SGRAM of the memory apparatus to the host system and/or latency for generating the read clock signal). Accordingly, by generating the read clock signal using the intermediate clock frequency, the quantity stages used to generate the read clock signal may be reduced. Such a reduction may reduce latency associated with generating the read clock signal may be reduced. Further, the die size of the memory apparatus may be reduced, manufacturing costs associated with the memory apparatus may be reduced, and/or the complexity of the design of the memory apparatus may be reduced (e.g., by reducing the amount of circuitry used to implement the read clock signal).

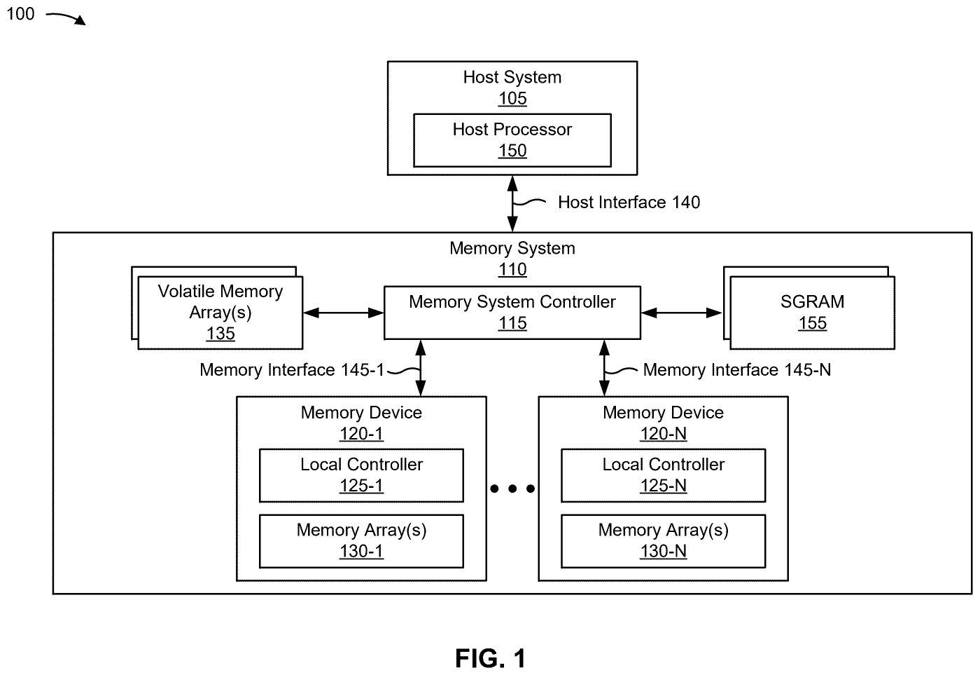

FIG. 1 is a diagram illustrating an example system 100 capable of read clock generation for SGRAM. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array, a SGRAM array, or a DRAM array). In some implementations, the memory system 110 may include one or more volatile memory arrays 135. A volatile memory array 135 may include an SRAM array, an SGRAM array, and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

The memory system may include an SGRAM 155. In some examples, SGRAM 155 may include one or more memory arrays used to store data associated with video memory (e.g., memory used for graphics rendering). In some cases, the SGRAM 155 may be associated with a synchronized clock signal, such as a read clock signal synchronized with an external clock signal (e.g., a clock signal provided by the host system 105). For example, the memory system 110 may include circuitry configured to generate a read clock signal the is synchronized with the external clock signal. As part of a memory access command to retrieve data stored in the SGRAM 155, the memory system 110 may provide the read clock signal and the data to the host system 105. The host system 105 may interpret the data (e.g., latch data included in a data signal) using the read clock signal. In some examples, the SGRAM 155 may be included in one or memory arrays of the memory system 110, such as the volatile memory array(s) 135 and/or the memory array(s) 130. Additionally, or alternatively, the SGRAM 155 may be a separate from the volatile memory array(s) 135 and/or the memory array(s) 130.

In some implementations, one or more systems, devices, apparatuses, components, and/or controllers of FIG. 1 may include an SGRAM 155 associated with a first clock signal having a first clock frequency; a mode register configured to provide one or more control parameters for read clock generation associated with the SGRAM 155; a command address decoder configured to provide one or more command parameters associated with a memory access command for the SGRAM 155; a read clock control component configured to generate read clock data based on the one or more control parameters and a second clock signal having a second clock frequency that is double the first clock frequency; and a read clock generator configured to generate a read clock signal having a third clock frequency that is double the second clock frequency based on the read clock data and the second clock signal.

In some implementations, one or more systems, devices, apparatuses, components, and/or controllers of FIG. 1 may include an SGRAM 155 associated with a first clock signal having a first clock frequency; a mode register configured to provide one or more control parameters for read clock generation associated with the SGRAM 155; one or more combinational circuits configured to generate read clock data based on the one or more control parameters; a first serialization component configured to obtain a first portion of the read clock data from the one or more combinational circuits based on a second clock signal having a second clock frequency that is double the first clock frequency; a second serialization component configured to obtain a second portion of the read clock data from the one or more combinational circuits based on the second clock frequency; and a driver configured to: obtain, from the first serialization component, the first portion of the read clock data; obtain, from the second serialization component, the second portion of the read clock data; and output, based on the first portion of the read clock data and the second portion of the read clock data, a read clock signal having a third clock frequency that is double the second clock frequency.

In some implementations, one or more systems, devices, apparatuses, components, and/or controllers of FIG. 1 may be configured to receive a command to initiate a read clock; generate read clock data based on one or more control parameters stored to a mode register and a second clock signal having a second clock frequency that is double the first clock frequency; and output a read clock signal that is based on the read clock data, the read clock signal having a third clock frequency that is double the second clock frequency, wherein the read clock signal is associated with a memory access command for the SGRAM 155.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

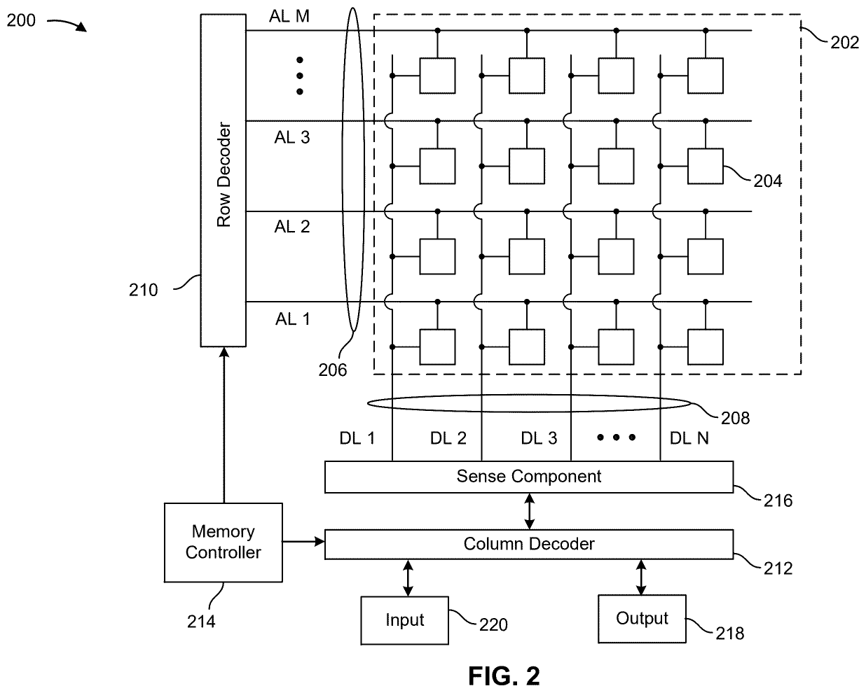

FIG. 2 is a diagrammatic view of an example memory device 200. The memory device 200 may include a memory array 202 that includes multiple memory cells 204. A memory cell 204 is programmable or configurable into a data state of multiple data states (e.g., two or more data states). For example, a memory cell 204 may be set to a particular data state at a particular time, and the memory cell 204 may be set to another data state at another time. A data state may correspond to a value stored by the memory cell 204. The value may be a binary value, such as a binary 0 or a binary 1, or may be a fractional value, such as 0.5, 1.5, or the like. A memory cell 204 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 204 by activating or selecting the appropriate access line 206 (shown as access lines AL 1 through AL M) and digit line 208 (shown as digit lines DL 1 through DL N). An access line 206 may also be referred to as a “row line” or a “word line,” and a digit line 208 may also be referred to a “column line” or a “bit line.” Activating or selecting an access line 206 or a digit line 208 may include applying a voltage to the respective line. An access line 206 and/or a digit line 208 may comprise, consist of, or consist essentially of a conductive material, such as a metal (e.g., copper, aluminum, gold, titanium, or tungsten) and/or a metal alloy, among other examples. In FIG. 2, each row of memory cells 204 is connected to a single access line 206, and each column of memory cells 204 is connected to a single digit line 208. By activating one access line 206 and one digit line 208 (e.g., applying a voltage to the access line 206 and digit line 208), a single memory cell 204 may be accessed at (e.g., is accessible via) the intersection of the access line 206 and the digit line 208. The intersection of the access line 206 and the digit line 208 may be called an “address” of a memory cell 204.

In some implementations, the logic storing device of a memory cell 204, such as a capacitor, may be electrically isolated from a corresponding digit line 208 by a selection component, such as a transistor. The access line 206 may be connected to and may control the selection component. For example, the selection component may be a transistor, and the access line 206 may be connected to the gate of the transistor. Activating the access line 206 results in an electrical connection or closed circuit between the capacitor of a memory cell 204 and a corresponding digit line 208. The digit line 208 may then be accessed (e.g., is accessible) to either read from or write to the memory cell 204.

A row decoder 210 and a column decoder 212 may control access to memory cells 204. For example, the row decoder 210 may receive a row address from a memory controller 214 and may activate the appropriate access line 206 based on the received row address. Similarly, the column decoder 212 may receive a column address from the memory controller 214 and may activate the appropriate digit line 208 based on the column address.

Upon accessing a memory cell 204, the memory cell 204 may be read (e.g., sensed) by a sense component 216 to determine the stored data state of the memory cell 204. For example, after accessing the memory cell 204, the capacitor of the memory cell 204 may discharge onto its corresponding digit line 208. Discharging the capacitor may be based on biasing, or applying a voltage, to the capacitor. The discharging may induce a change in the voltage of the digit line 208, which the sense component 216 may compare to a reference voltage (not shown) to determine the stored data state of the memory cell 204. For example, if the digit line 208 has a higher voltage than the reference voltage, then the sense component 216 may determine that the stored data state of the memory cell 204 corresponds to a first value, such as a binary 1. Conversely, if the digit line 208 has a lower voltage than the reference voltage, then the sense component 216 may determine that the stored data state of the memory cell 204 corresponds to a second value, such as a binary 0. The detected data state of the memory cell 204 may then be output (e.g., via the column decoder 212) to an output component 218 (e.g., a data buffer). A memory cell 204 may be written (e.g., set) by activating the appropriate access line 206 and digit line 208. The column decoder 212 may receive data, such as input from input component 220, to be written to one or more memory cells 204. A memory cell 204 may be written by applying a voltage across the capacitor of the memory cell 204.

The memory controller 214 may control the operation (e.g., read, write, re-write, refresh, and/or recovery) of the memory cells 204 via the row decoder 210, the column decoder 212, and/or the sense component 216. The memory controller 214 may generate row address signals and column address signals to activate the desired access line 206 and digit line 208. The memory controller 214 may also generate and control various voltages used during the operation of the memory array 202.

In some implementations, the memory device 200 may include, or may be associated with, an SGRAM (e.g., the SGRAM 155). For example, the memory array 202 may be an example of an array of SGRAM memory cells. In some cases, to support an increased bandwidth, the memory device 200 may be associated with a synchronized clock signal, such as a read clock signal synchronized with an external clock signal. For example, the memory device 200 may include or may be associated with circuitry configured to generate a read clock signal the is synchronized with the external clock signal. As part of a memory access command to retrieve data stored in the memory array 202, the memory device 200 may provide the read clock signal and the data to a host system. The host system may interpret the data (e.g., latch data included in a data signal) using the read clock signal.

As indicated above, FIG. 2 is provided as an example. Other examples may differ from what is described with respect to FIG. 2.

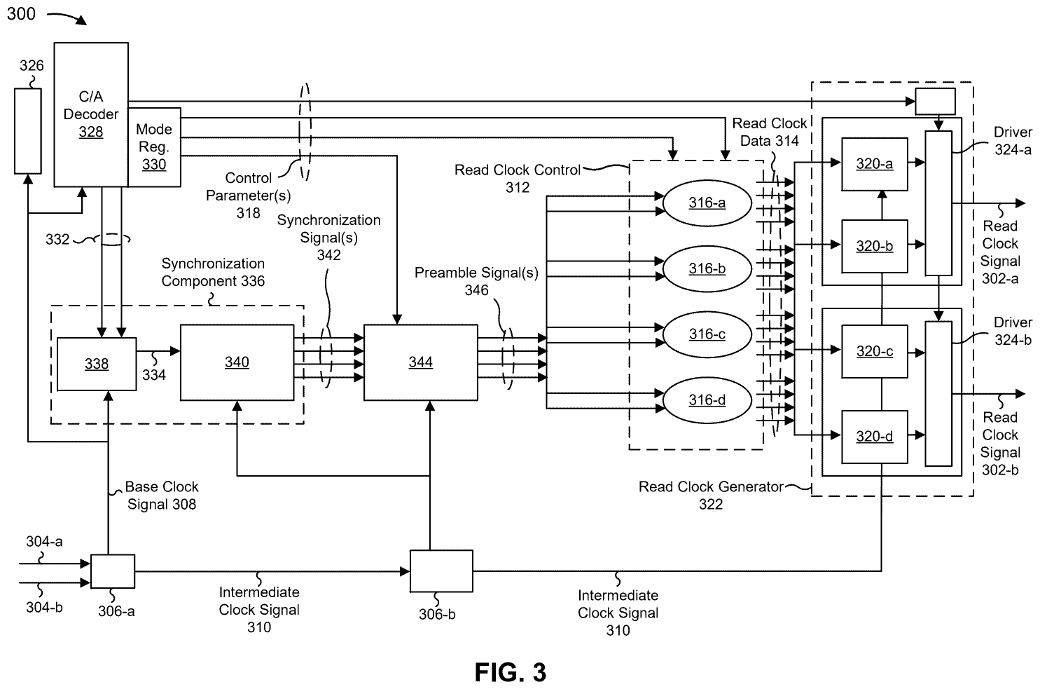

FIG. 3 is a diagram illustrating an example of a system 300 that supports read clock generation for SGRAM. The system 300 may include aspects of and/or may be implemented by a memory apparatus, such as the memory system 110 and/or a memory device 120. For example, the system 300 may be implemented in the memory system controller 115, in a local controller 125, and/or elsewhere within the memory apparatus. In some implementations, the system 300 may be implemented near one or more SGRAMs (e.g., the SGRAM 155). For example, the system 300 may be implemented physically close to the SGRAM(s), such as by being included in the same package (e.g., included in the same system on a chip (SoC)) as the SGRAM(s). Additionally, or alternatively, the system 300 may be implemented in a controller associated with the SGRAM(s), such as a memory system controller 115, a local controller 125, and/or a memory controller 214. The memory apparatus may implement (e.g., generate and transmit) a read clock signal 302. The memory apparatus may provide the read clock signal 302 to a host system, such as the host system 105 using the host interface 140, in response to a memory access command (e.g., a read command) from the host system. The host system may use the read clock signal 302 as part of interpreting a data signal from the SGRAM(s) containing data associated with the read command, such as by latching the data using the read clock signal 302. For example, because the SGRAM(s) and the system 300 may be implemented within the memory apparatus, variations in the data signal (e.g., variations due to changes in temperature and/or supply voltage) may be similar to (e.g., mirrored by) variations in the read clock signal 302. Accordingly, misalignments between the data signal and the read clock signal 302 may be reduced.

The memory apparatus may generate one or more read clock signals 302 using one or more internal clock signals that are based on one or more external clock signals 304 received from the host system (e.g., via the host interface 140). Such internal clock signal(s) may have a reduced frequency compared with the external clock signal(s) 304. In some implementations, the external clock signal(s) 304 may form a differential clock signal. For example, the external clock signal(s) 304 may include a clock signal 304-a and a clock signal 304-b that is shifted in phase by 180 degrees (e.g., by half of the period of the external clock signal(s) 304), such that the clock signal 304-b is the inverse of the clock signal 304-a.

The memory apparatus may generate, using one or more signal processing components 306, a base clock signal 308 having a base frequency (e.g., a frequency one quarter of the frequency of the external clock signal 304). The one or more signal processing components 306 (shown in FIG. 3 as signal processing component 306-a and signal processing component 306-b) may generate an intermediate clock signal 310 having an intermediate clock frequency that is double the base frequency. In some implementations, the base clock signal 308 and/or the intermediate clock signal 310 may be examples of a multi-phase clock signal. As described herein, “multi-phase clock signal” may refer to a group of clock signals having the same frequency, in which each clock signal is associated with a different phase of the multi-clock signal. For example, the intermediate clock signal 310 may include a first clock signal (e.g., a first phase), a second clock signal (e.g., a second phase) shifted in phase by 90 degrees (e.g., by one quarter of the period of the intermediate clock signal 310), a third clock signal (e.g., a third phase) shifted in phase by 180 degrees (e.g., by one half of the period of the intermediate clock signal 310), and a fourth clock signal (e.g., a fourth phase) shifted in phase by 270 degrees (e.g., by three quarters of the period of the intermediate clock signal 310).

The memory apparatus may include a read clock control component 312 configured to generate read clock data 314. In some implementations, the read clock data 314 may include one or more sequences of binary data. For example, the read clock data 314 may include one or more nibbles. As described herein, a nibble may be a sequence of four binary values, such as “0101”. A nibble of the read clock data 314 may be an input to a serialization component 320 to enable the generation a read clock signal 302, as described in greater detail elsewhere herein. The read clock control component 312 may provide the read clock data 314 to a read clock generator 322.

In some cases, the read clock control component 312 may include one or more combinational circuits 316 (shown in FIG. 3 as combinational circuit 316-a, combinational circuit 316-b, combinational circuit 316-c, and combinational circuit 316-d) that generate the read clock data 314 based on one or more control parameters 318. For example, a combinational circuit 316 may include one or more logic circuits, such as gates and/or multiplexers, configured to output all, or a portion of, the read clock data 314 based one or more inputs to the combinational circuit 316. The memory apparatus may provide the control parameters 318 to the one or more combinational circuits 316 (e.g., as an input) to determine the read clock data 314. The read clock control component 312 may be configured to output different read clock data 314 for different values of the control parameter(s). In some examples, the memory apparatus may store the control parameter(s) to a mode register 330. In such examples, the host system may configure the control parameter(s) 318, for example using a mode register set command.

The read clock generator 322 may generate a read clock signal 302 having a frequency that is equal to the external clock frequency (e.g., double the intermediate clock frequency, quadruple the base clock frequency). In some implementations, the read clock generator 322 may include one or more serialization components 320 (shown in FIG. 3 as serialization component 320-a, serialization component 320-b, serialization component 320-c, and serialization component 320-d) that obtain all, or a portion of, the read clock data 314 from the read clock control component 312. For example, a serialization component 320 may obtain a portion of the read clock data (e.g., a nibble) as an input. Additionally, a serialization component 320 may obtain a clock signal, such as the intermediate clock signal 310. The serialization component 320 may selectively output a single value at a time (e.g., a high value and/or a low value, a logic “1” and/or a logic “0”) based on the obtained clock signal. As used herein, “selectively” performing an operation means to either perform the operation or refrain from performing the operation. For example, selectively performing an operation based on whether a condition is satisfied means that the operation is performed if the condition is satisfied and that the operation is not performed if the condition is not satisfied (or vice versa). Thus, selectively performing an operation may include determining whether to perform the operation and then either performing the operation or refraining from performing the operation based on that determination. As used herein, “selectively” performing a first operation or a second operation means to perform either the first operation or the second operation. For example, selectively performing a first operation or a second operation based on whether a condition is satisfied means that the first operation is performed if the condition is satisfied and that the second operation is performed if the condition is not satisfied (or vice versa). Thus, selectively performing a first operation or a second operation may include determining whether to perform either the first operation or the second operation and then performing either the first operation or the second operation based on that determination.

For example, if the subset of the read clock data 314 provided to a serialization component 320 includes the nibble “1010”, then the serialization component 320 may output a logic “1” in response to a rising edge (e.g., at the rising edge) of a first phase of the intermediate clock signal 310, followed by a logic “0” in response to a rising edge of a second phase of the intermediate clock signal 310, followed by a logic “1” in response to a rising edge of a third phase of the intermediate clock signal 310, followed by a logic “0” in response to a rising edge of a fourth phase of the intermediate clock signal 310. Accordingly, the serialization component 320 may cycle through the bits of the input nibble, such that the output of the serialization component 320 encodes a serialized version of the input nibble. Further, due to the timing of the phases of the intermediate clock signal 310, the frequency of the output signal of the serialization component 320 may be double the frequency of the intermediate clock signal 310 (e.g., quadruple the base clock frequency, equal to the external clock frequency).

The read clock generator 322 may include one or more drivers 324 configured to obtain an output signal of one or more serialization components 320 (e.g., as one or more inputs to the one or more drivers 324). In some implementations, the output of a driver 324 may be based on the one or more inputs to the driver 324. For example, a driver 324 may be configured to encode multiple (e.g., two) signal levels corresponding to the inputs into a single output signal level. In some implementations, the output of a driver may be one of multiple (e.g., 3) possible values, such as a value corresponding to a ternary digit. Such values may have a voltage level that is a percentage of a supply voltage of the memory apparatus. For example, a driver 324 may be a three-level pulse amplitude modulation (PAM3) driver. Table 1 illustrates a mapping between signal levels of input signals and the signal level of the output of a driver 324. Although specific combinations are included herein, other mappings are also possible.

TABLE 1

| First | Second | Ternary | Percent of |
|---|---|---|---|
| Input | Input | Digit | Supply Voltage |
| 1 | 1 | 1 | 100 |
| 1 | 0 | Undefined | Undefined |
| 0 | 1 | 0 | 75 |
| 0 | 0 | −1 | 50 |

Accordingly, by inputting a serialized form of the read clock data 314, the read clock generator 322 may output a read clock signal 302 having a frequency equal to the external clock frequency using the intermediate clock signal 310. Such an implementation may improve performance of the memory apparatus. For example, if a memory apparatus employs the base clock signal 308 to generate the read clock signal 302, then the memory apparatus may include additional signal processing stages (e.g., additional serialization components 320 or other signal processing circuitry) to generate the read clock signal 302. Such additional stages may cause added delay associated with generating the read clock signal 302, which may in turn increase latency. Accordingly, by generating the read clock signal 302 using the intermediate clock signal 310, the quantity stages used to generate the read clock signal 302 may be reduced. Such a reduction may reduce latency associated with generating the read clock signal 302. Further, the die size of the memory apparatus may be reduced, manufacturing costs associated with the memory apparatus may be reduced, and/or the complexity of the design of the memory apparatus may be reduced (e.g., by reducing the amount of circuitry used to implement the read clock signal 302).

In some implementations, the read clock generator 322 may generate multiple read clock signals 302. For example, the read clock generator 322 may include a driver 324-a configured to receive a first portion of the read clock data 314 and a driver 324-b configured to receive a second portion of the read clock data 314. In such implementations, the read clock signal 302-b may be a complimentary signal to the read clock signal 302-a, such that the read clock signal 302-a and the read clock signal 302-b form a differential signal. For example, the read clock signal 302-b may be a complimentary signal to the read clock signal 302-a (e.g., inverted with respect to the read clock signal 302-a), such that a rising edge of the read clock signal 302-a corresponds to a falling edge of the read clock signal 302-b and a falling edge of the read clock signal 302-a corresponds to a rising edge of the read clock signal 302-b. In some implementations, to generate the differential signal, the first portion of read clock data 314 provided to the serialization components 320-a and 320-b may be the inverse of the second portion of the read clock data provided to the serialization components 320-c and 320-d. For example, if the read clock data 314 includes a first nibble “0101” provided to the serialization component 320-a and a second nibble “0101” provided to the serialization component 320-b, then the read clock data 314 may include a third nibble “1010” (e.g., the inverse of the first nibble) provided to the serialization component 320-c and a fourth nibble “1010” (e.g., the inverse of the second nibble) provided to the serialization component 320-d. Alternatively, the read clock generator 322 may generate a single ended read clock signal. For example, to generate the single ended read clock signal, the driver 324-a of the read clock generator 322 may generate the read clock signal 302-a as described herein. In such examples, the driver 324-b may output a constant value (e.g., a high voltage state, a high-impedance (hi-Z) state) to generate the singe ended read clock signal.

In some implementations, the memory apparatus may generate the read clock signal 302 based on (e.g., in response to) receiving a command from the host system. For example, the memory apparatus may include command and address (C/A) receiver 326 and a C/A decoder 328. In some cases, the read clock data 314 may be based on one or more control parameters 318 stored in a mode register 330 of the memory apparatus. In such examples, as part of generating the read clock signal 302, the memory apparatus may provide one or more of the control parameters 318 to the read clock control component 312, a preamble signal generator 344, and/or a synchronization component 336.

For example, the one or more control parameters 318 may include a swing parameter. The memory apparatus may provide the swing parameter to the read clock control component 312. The swing parameter may include an indication of whether to generate a full swing read clock signal or a half swing read clock signal. As described herein, a full swing read clock signal may refer to a read clock signal that alternates (e.g., toggles) between a high voltage level (e.g., 100 percent of the supply voltage, a ternary digit of “1”), and a low voltage level (e.g., 50 percent of the supply voltage, a ternary digit of “−1”). A half swing read clock signal may refer to a read clock signal that alternates (e.g., toggles) between a high voltage level (e.g., 100 percent of the supply voltage, a ternary digit of “1”), and an intermediate voltage level (e.g., 75 percent of the supply voltage, a ternary digit of “0”).

The read clock control component 312 may obtain the swing parameter and may generate read clock data 314 based on the value of the swing parameter. For example, if the swing parameter is a first value (e.g., a logic “1”), then the read clock control component may generate “full swing” read clock data 314 (e.g., read clock data 314 configured to cause the one or more drivers 324 to output a full swing read clock signal). The read clock control component 312 may provide, and the read clock generator 322 may obtain, the full swing read clock data. The read clock generator 322 may use the full swing read clock data generate a full swing read clock signal. Alternatively, if the swing parameter is a second value (e.g., a logic “0”), then the read clock control component 312 may generate “half swing” read clock data (e.g., read clock data configured to cause the one or more drivers 324 to output a half swing read clock signal). The read clock control component 312 may provide, and the read clock generator 322 may obtain, the half swing read clock data. The read clock generator 322 may use the half swing read clock data generate a half swing read clock signal.

In some examples, the one or more control parameters 318 may include a synchronization parameter. The memory apparatus may provide the synchronization parameter (e.g., a duration parameter) to the synchronization component 336. The synchronization component 336 may be configured to cause the memory apparatus to initiate the read clock signal 302 after a synchronization duration from receiving the command. The synchronization parameter may include an indication of whether a synchronous read clock signal is to be generated. As described herein, “synchronous” clock signal refers to a read clock signal 302 that is initiated after the synchronization duration from the memory apparatus receiving a command. For example, the synchronization component 336 may include a synchronizer 338. After receiving a command to initiate the read clock signal 302, the C/A decoder 328 may provide a signal 332 indicating the synchronization parameter to the synchronizer 338. In some implementations, the synchronizer 338 may provide a signal 334 indicating the synchronization parameter to a synchronization signal generator 340 after the synchronization duration. After receiving the signal, the synchronization signal generator may provide one or more synchronization signals 342 to the read clock control component 312. The read clock control component 312 may be configured to output the read clock data 314 (e.g., in response to) obtaining the synchronization signal(s) 342. Accordingly, by providing the synchronization parameter to the synchronization component 336, the memory apparatus may initiate the read clock signal 302 after the synchronization duration from receiving the command. In some examples, the synchronization duration may be indicated by the command. Additionally, or alternatively, the synchronization duration may be stored by the memory apparatus, such as in the mode register 330. In such cases, the synchronization duration may be configured, for example by a configuration command from the host system.

In some examples, the memory apparatus may be configured to generate an asynchronous read clock signal. As described herein, “asynchronous” clock signal refers to a read clock signal 302 that is initiated within a given duration, referred to herein as an asynchronous duration, from the memory apparatus receiving a command. For example, to generate an asynchronous clock signal, the memory apparatus may initiate the read clock signal 302 at any time within the asynchronous duration from receiving the command. In some examples, the asynchronous duration may be indicated by the command. Additionally, or alternatively, the asynchronous duration may be stored by the memory apparatus, such as in the mode register 330. In such cases, the asynchronous duration may be configured, for example by a configuration command from the host system. In some examples, the command may include an indication of whether to generate a synchronous clock signal or an asynchronous clock signal. Additionally, or alternatively, the memory apparatus may store an indication of whether to generate a synchronous clock signal or an asynchronous clock signal, such as in the mode register 330. In such cases, the indication may be configured, for example by a configuration command from the host system.

In some examples, the one or more control parameters 318 may include a preamble parameter. The memory apparatus may provide the preamble parameter to the preamble signal generator 344. The preamble signal generator 344 may cause the memory apparatus to generate a preamble read clock signal prior to generating the read clock signal. The preamble parameter may include an indication of whether to generate the preamble read clock signal. As described herein, “preamble” read clock signal refers to a read clock signal provided prior to the read clock signal 302. A preamble read clock signal may have a frequency that is less than (e.g., half) the frequency of the read clock signal 302 (e.g., equal to the intermediate clock frequency, double the base clock frequency). In some examples, the host system may use the preamble read clock signal to identify the beginning of the read clock signal 302.

For example, after receiving a command to initiate the read clock signal 302, the C/A decoder 328 may provide the preamble parameter to the preamble signal generator 344. After receiving the preamble parameter, the preamble signal generator 344 may provide one or more preamble signals 346 to the read clock control component 312. The read clock control component 312 may be configured to output read clock data 314 configured to cause the read clock generator 322 to output the preamble read clock signal after (e.g., in response to) obtaining the preamble signal(s) 346. In some cases, the preamble signal generator 344 may output the preamble signal(s) 346 for a preamble duration after receiving the preamble parameter. In some examples, the preamble duration may be indicated by the command. Additionally, or alternatively, the preamble duration may be stored by the memory apparatus, such as in the mode register 330. In such cases, the preamble duration may be configured, for example by a configuration command from the host system. After the preamble duration has expired, the preamble signal generator 344 may output one or more signals to the read clock control component 312 indicating that the read clock control component 312 is to refrain from generating the preamble read clock signal. For example, the preamble signal generator 344 may include a counter. The preamble signal generator 344 may obtain the intermediate clock signal 310. The preamble signal generator 344 may count a quantity of cycles of the intermediate clock signal 310 (e.g., via the counter) to determine whether the preamble duration has expired based on the value of the counter satisfying a threshold corresponding to the preamble duration. In some examples, the threshold may be a quantity of cycles indicated by a quantity parameter of the control parameters 318. In such examples, the quantity parameter may correspond to the quantity of cycles (e.g., periods) of the intermediate clock signal 310 whose sum is equal to the preamble duration.

Accordingly, by providing the preamble parameter to the preamble signal generator 344, the memory apparatus may output a preamble read clock signal for the preamble duration. After the preamble duration has expired, the memory apparatus may output the read clock signal 302. Table 2 may illustrate examples of portions of the read clock data 314 (e.g., nibbles) provided to the serialization components 320 to generate a full swing preamble read clock signal, a half swing preamble read clock signal, a full swing read clock signal, and/or a half swing read clock signal. Although specific values of the read clock data 314 are included herein other values are also possible.

TABLE 2

| | | Input to | Input to | Input to | Input to |
|---|---|---|---|---|---|
| | | Serial- | Serial- | Serial- | Serial- |
| | | ization | ization | ization | ization |
| | | Compo- | Compo- | Compo- | Compo- |
| | | nent | nent | nent | nent |
| | | 320-a | 320-b | 320-c | 320-d |
| Preamble | Full | 0011 | 0011 | 1100 | 1100 |
| Read | Swing | | | | |
| Clock | Half | 0011 | 1111 | 1100 | 1111 |
| Signal | Swing | | | | |
| Read | Full | 0101 | 0101 | 1010 | 1010 |
| Clock | Swing | | | | |
| Signal | Half | 0101 | 1111 | 1010 | 0000 |
| | Swing | | | | |

As indicated above, FIG. 3 is provided as an example. Other examples may differ from what is described with regard to FIG. 3.

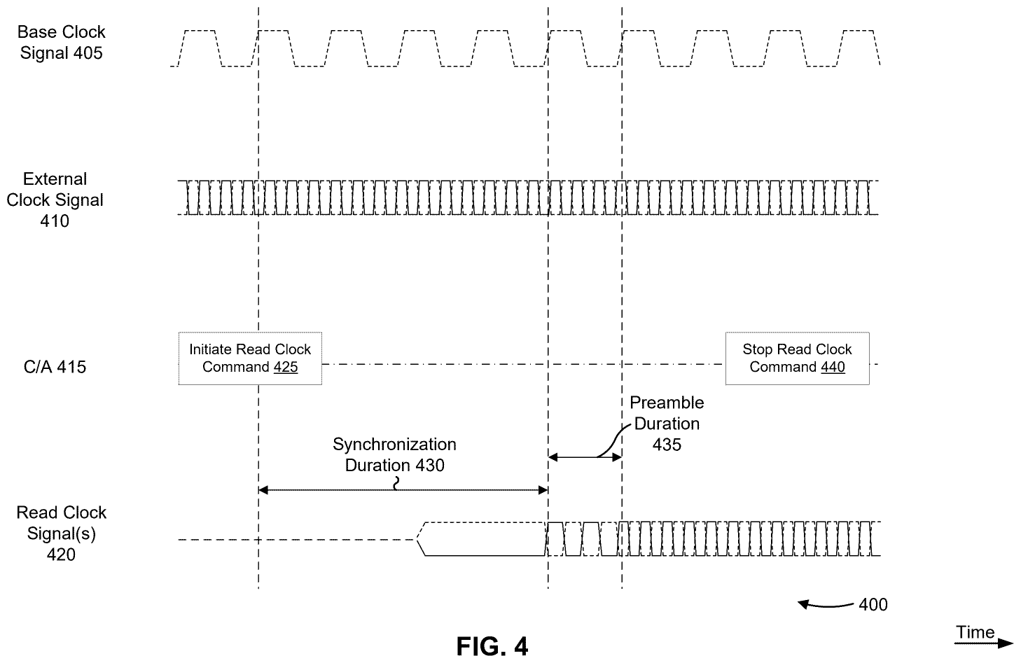

FIG. 4 is a diagram illustrating an example of a timing diagram 400 that supports read clock generation for SGRAM. The timing diagram 400 may illustrate timing aspects of signals communicated over and/or associated with one or more channels of an interface between a host system, such as the host system 105, and a memory apparatus, such as the memory system 110 and/or a memory device 120. For example, the timing diagram may illustrate a base clock signal 405 associated with an external clock signal 410. The external clock signal 410 may be an example of the external clock signal 304.

The timing diagram 400 may illustrate one or more commands transmitted to the memory apparatus from the host system via a C/A channel 415. For example, the host system may provide, and the memory apparatus may obtain, a command 425. In some cases, the command 425 may be a command to initiate the read clock of the memory apparatus, such as a read clock start (RCKSTART) command and/or a read training (RDTR) command. Additionally, or alternatively, the command 425 may indicate other operations to be performed by the memory apparatus. For example, the command 425 may be a read (RD) command to retrieve data from the memory apparatus. In such cases, the memory apparatus may initiate the read clock as part of performing the operations (e.g., as part of performing the read command). In some examples, the command 425 may include one or more command parameters, which may be examples of the control parameter(s) 318. Additionally, or alternatively, the memory apparatus may store the control parameter(s) 318 in a mode register.

In response to, based on, or otherwise associated with receiving the command 425, the memory apparatus may generate the read clock signal 420. In some implementations, the read clock signal 420 may be a synchronous read clock signal. For example, the command 425 may include a synchronization parameter that indicates the memory apparatus is to generate the synchronous read clock signal. The memory apparatus may initiate the read clock signal 420 by a synchronization duration 430 from receiving the command 425. For example, the memory apparatus may include a synchronization component (e.g., the synchronization component 336) configured to cause the memory apparatus to initiate the read clock signal 420 after the synchronization duration 430, as described in greater detail elsewhere herein.

In some examples, the memory apparatus may output a preamble read clock signal for a preamble duration 435 prior to outputting the read clock signal 420. For example, the command 425 may include a preamble parameter that indicates the memory apparatus is to generate the preamble read clock signal. For example, the memory apparatus may include a preamble signal generator (e.g., the preamble signal generator 344) configured generate one or more preamble signals to cause the memory apparatus to output a preamble read clock signal for the preamble duration, as described in greater detail elsewhere herein. After the preamble duration has expired, the memory apparatus may output the read clock signal 420. In some examples, the host system may transmit, and the memory apparatus may receive, a stop read clock command 440 via the C/A channel 415. In response to, based on, or otherwise associated with receiving the stop read clock command 440, the memory apparatus may refrain from generating the read clock signal(s) 420.

As indicated above, FIG. 4 is provided as an example. Other examples may differ from what is described with regard to FIG. 4.

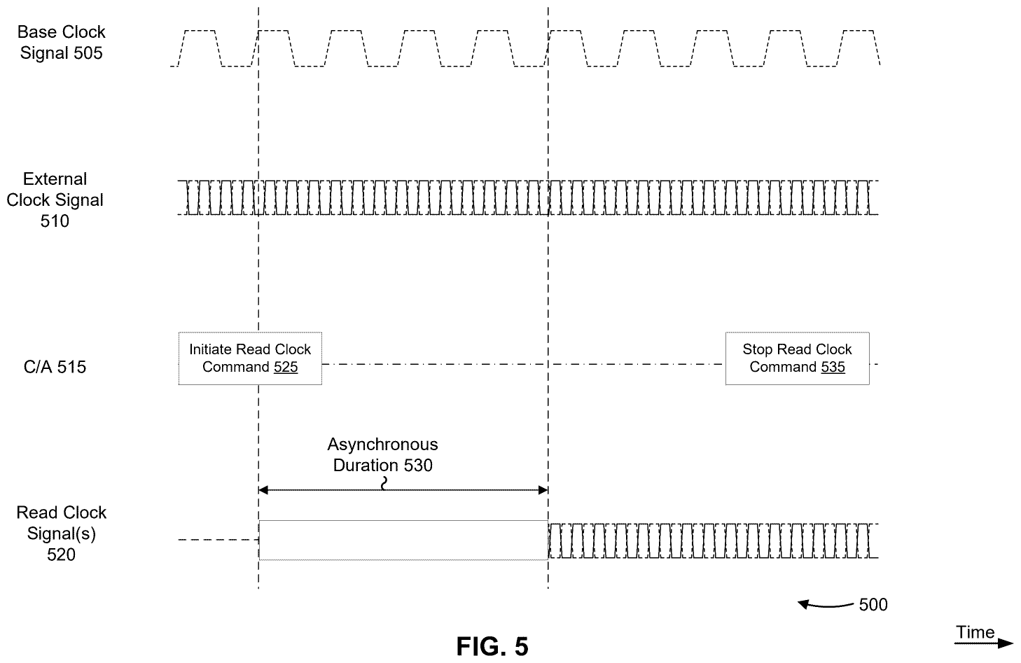

FIG. 5 is a diagram illustrating an example of a timing diagram 500 that supports read clock generation for SGRAM. The timing diagram 500 may illustrate timing aspects of signals communicated over and/or associated with one or more channels of an interface between a host system, such as the host system 105, and a memory apparatus, such as the memory system 110 and/or a memory device 120. For example, the timing diagram 500 may illustrate a base clock signal 505 associated with an external clock signal 510. The external clock signal 510 may be an example of the external clock signal 304.

The timing diagram 500 may illustrate one or more commands transmitted to the memory apparatus from the host system via a C/A channel 515. For example, the host system may provide, and the memory apparatus may obtain, a command 525. In some cases, the command 525 may be a command to initiate the read clock of the memory apparatus. Additionally, or alternatively, the command 525 may indicate other operations to be performed by the memory apparatus. For example, the command 525 may be a read command to retrieve data from the memory apparatus. In such cases, the memory apparatus may initiate the read clock as part of performing the operations (e.g., as part of performing the read command). In some examples, the command 525 may include one or more command parameters, which may be examples of the control parameter(s) 318. Additionally, or alternatively, the memory apparatus may store the control parameter(s) 318 to a mode register.

In response to, based on, or otherwise associated with receiving the command 525, the memory apparatus may generate the read clock signal 520. In some implementations, the read clock signal 520 may be an asynchronous read clock signal. For example, the command 525 may include a synchronization parameter that indicates the memory apparatus is to generate the asynchronous read clock signal. The memory apparatus may initiate the read clock signal 520 within an asynchronous duration 530 from receiving the command 525, as described in greater detail elsewhere herein. As described herein, initiating the read clock signal 520 within the asynchronous duration 530 may include beginning to generate the read clock signal 520 after receiving the command 525 and before the expiration of the asynchronous duration 530, such that the memory apparatus ensures that the read clock signal has been initiated after the expiration of the asynchronous duration 530. In some examples, the host system may transmit, and the memory apparatus may receive, a stop read clock command 535 via the C/A channel 515. In response to, based on, or otherwise associated with receiving the stop read clock command 535, the memory apparatus may refrain from generating the read clock signal(s) 520.

As indicated above, FIG. 5 is provided as an example. Other examples may differ from what is described with regard to FIG. 5.

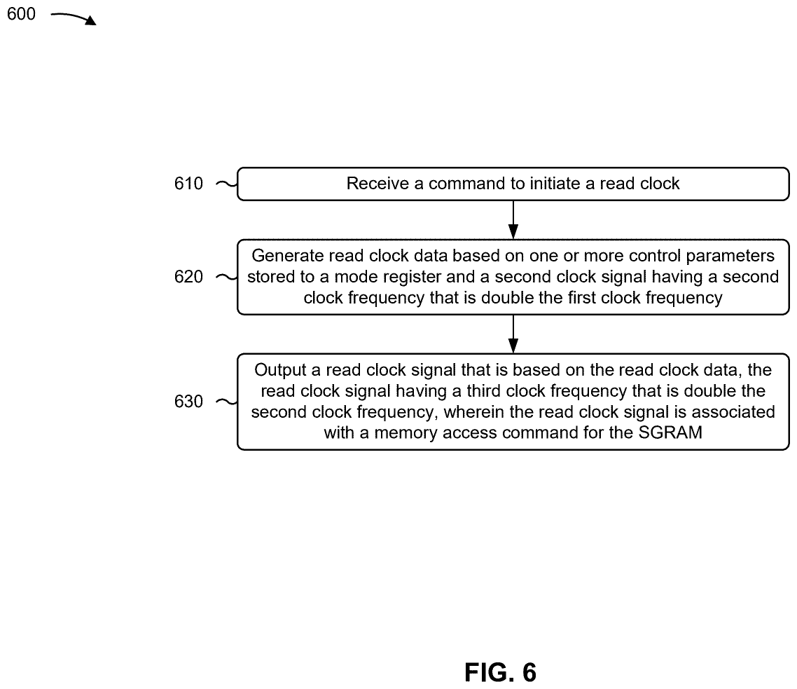

FIG. 6 is a flowchart of an example method 600 associated with read clock generation for SGRAM. In some implementations, a memory apparatus (e.g., a memory system 110 and/or a memory device 120) may perform or may be configured to perform the method 600. In some implementations, another device or a group of devices separate from or including the memory apparatus (e.g., the host system 105, the host processor 150, and/or the host interface 140) may perform or may be configured to perform the method 600. Additionally, or alternatively, one or more components of the memory apparatus (e.g., the memory system 110, one or more memory devices 120, a memory system controller 115, a local controller 125, and/or a memory controller 214) may perform or may be configured to perform the method 600. Thus, means for performing the method 600 may include the memory apparatus and/or one or more components of the memory apparatus. Additionally, or alternatively, a non-transitory computer-readable medium may store one or more instructions that, when executed by the memory apparatus, cause the memory apparatus to perform the method 600.

As shown in FIG. 6, the method 600 may include receiving, by a memory apparatus comprising an SGRAM associated with a first clock signal having a first clock frequency, a command to initiate a read clock (block 610). As further shown in FIG. 6, the method 600 may include generating read clock data based on one or more control parameters stored to a mode register and a second clock signal having a second clock frequency that is double the first clock frequency (block 620). As further shown in FIG. 6, the method 600 may include outputting a read clock signal that is based on the read clock data, the read clock signal having a third clock frequency that is double the second clock frequency, wherein the read clock signal is associated with a memory access command for the SGRAM (block 630).

The method 600 may include additional aspects, such as any single aspect or any combination of aspects described below and/or described in connection with one or more other methods or operations described elsewhere herein.

In a first aspect, generating the read clock data includes determining subsets of the read clock data via respective combinational circuits of the one or more combinational circuits, where the subsets of the read clock data are based on the one or more control parameters.

In a second aspect, alone or in combination with the first aspect, the method 600 includes providing one or more synchronization signals to the one or more combinational circuits based on a synchronization parameter of the one or more control parameters, where determining the subsets of the read clock data is based on the one or more synchronization signals, and transmitting, based on the one or more synchronization signals, the read clock signal after a duration from a time at which the command is obtained, the duration indicated by a duration parameter of the one or more control parameters, where transmitting the read clock signal is based on initiating the read clock signal.

In a third aspect, alone or in combination with one or more of the first and second aspects, the method 600 includes providing one or more preamble signals to the one or more combinational circuits based on a preamble parameter of the one or more control parameters, where determining the subsets of the read clock data is based on the one or more preamble signals, and transmitting, based on the one or more preamble signals, a preamble read clock signal prior to transmitting the read clock signal, where the preamble read clock signal has a fourth clock frequency that is half the third clock frequency.

In a fourth aspect, alone or in combination with one or more of the first through third aspects, the method 600 includes receiving a second command to store the one or more control parameters to the mode register, where the second command comprises an indication of the one or more control parameters.

In a fifth aspect, alone or in combination with one or more of the first through fourth aspects, the method 600 includes transmitting a second read clock signal based on the read clock data, where the second read clock signal is a complementary signal to the read clock signal, and where the read clock signal and the second read clock signal form a differential signal.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a system includes an SGRAM associated with a first clock signal having a first clock frequency; a mode register configured to provide one or more control parameters for read clock generation associated with the SGRAM; a command address decoder configured to provide one or more command parameters associated with a memory access command for the SGRAM; a read clock control component configured to generate read clock data based on the one or more control parameters and a second clock signal having a second clock frequency that is double the first clock frequency; and a read clock generator configured to generate a read clock signal having a third clock frequency that is double the second clock frequency based on the read clock data and the second clock signal.

In some implementations, a system includes an SGRAM associated with a first clock signal having a first clock frequency; a mode register configured to provide one or more control parameters for read clock generation associated with the SGRAM; one or more combinational circuits configured to generate read clock data based on the one or more control parameters; a first serialization component configured to obtain a first portion of the read clock data from the one or more combinational circuits based on a second clock signal having a second clock frequency that is double the first clock frequency; a second serialization component configured to obtain a second portion of the read clock data from the one or more combinational circuits based on the second clock frequency; and a driver configured to: obtain, from the first serialization component, the first portion of the read clock data; obtain, from the second serialization component, the second portion of the read clock data; and output, based on the first portion of the read clock data and the second portion of the read clock data, a read clock signal having a third clock frequency that is double the second clock frequency.

In some implementations, a method includes receiving, by a memory apparatus that includes an SGRAM associated with a first clock signal having a first clock frequency, a command to initiate a read clock; generating, by the memory apparatus, read clock data based on one or more control parameters stored to a mode register and a second clock signal having a second clock frequency that is double the first clock frequency; and outputting, by the memory apparatus, a read clock signal that is based on the read clock data, the read clock signal having a third clock frequency that is double the second clock frequency, wherein the read clock signal is associated with a memory access command for the SGRAM.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A system, comprising:
synchronous graphics random access memory (SGRAM) associated with a first clock signal having a first clock frequency;
a mode register configured to provide one or more control parameters for read clock generation associated with the SGRAM;
a command address decoder configured to provide one or more command parameters associated with a memory access command for the SGRAM;
a read clock control component configured to generate read clock data based on the one or more control parameters and a second clock signal having a second clock frequency that is double the first clock frequency; and
a read clock generator configured to generate a read clock signal having a third clock frequency that is double the second clock frequency based on the read clock data and the second clock signal.

2. The system of claim 1, wherein the read clock control component comprises:
one or more combinational circuits configured to provide respective subsets of the read clock data to the read clock generator based on the one or more control parameters.

3. The system of claim 2, wherein the read clock control component comprises:
a synchronization signal generator configured to provide one or more synchronization signals to the one or more combinational circuits based on a synchronization parameter of the one or more control parameters, wherein the one or more synchronization signals cause the read clock generator to initiate the read clock signal after a duration from a time at which the memory access command is obtained, the duration indicated by a duration parameter of the one or more control parameters.

4. The system of claim 2, wherein the read clock control component comprises:
a preamble signal generator configured to provide one or more preamble signals to the one or more combinational circuits, wherein the one or more preamble signals cause the read clock generator to generate a preamble read clock signal prior to generating the read clock signal, wherein the preamble read clock signal has a fourth clock frequency that is equal to the second clock frequency.

5. The system of claim 4, wherein the preamble signal generator comprises a counter configured to obtain the second clock signal, and wherein the preamble signal generator is configured to modify the one or more preamble signals based on a value of the counter satisfying a threshold.

6. The system of claim 4, wherein the preamble read clock signal comprises a quantity of cycles, wherein the quantity of cycles is based on a quantity parameter of the one or more control parameters.

7. The system of claim 1, wherein the read clock generator comprises:
a first serialization component configured to obtain the second clock signal;
a second serialization component configured to obtain the second clock signal; and
a first driver configured to:
obtain, based on the second clock signal, a first portion of the read clock data from the first serialization component;
obtain, based on the second clock signal, a second portion of the read clock data from the second serialization component; and
output the read clock signal based on the first portion of the read clock data and the second portion of the read clock data.

8. The system of claim 7, wherein the read clock generator comprises:
a third serialization component configured to obtain the second clock signal;
a fourth serialization component configured to obtain the second clock signal; and
a second driver configured to:
obtain, based on the second clock signal, a third portion of the read clock data from the third serialization component;
obtain, based on the second clock signal, a fourth portion of the read clock data from the fourth serialization component; and
output a second read clock signal based on the third portion of the read clock data and the fourth portion of the read clock data.

9. The system of claim 8, wherein the second read clock signal is a complementary signal to the read clock signal, and wherein the read clock signal and the second read clock signal form a differential signal.

10. The system of claim 8, wherein the first driver and the second driver are three-level pulse-amplitude modulation (PAM3) drivers.

11. The system of claim 1, wherein the read clock generator is further configured to generate a full swing for the read clock signal or generate a half swing for the read clock signal based on a swing parameter of the one or more control parameters.

12. The system of claim 1, wherein the read clock generator is configured to output the read clock signal within a duration from a time at which the memory access command is obtained, wherein the duration is based on a synchronization parameter of the one or more control parameters.

13. A system, comprising:
a synchronous graphics random access memory (SGRAM) associated with a first clock signal having a first clock frequency;
a mode register configured to provide one or more control parameters for read clock generation associated with the SGRAM;
one or more combinational circuits configured to generate read clock data based on the one or more control parameters;
a first serialization component configured to obtain a first portion of the read clock data from the one or more combinational circuits based on a second clock signal having a second clock frequency that is double the first clock frequency;
a second serialization component configured to obtain a second portion of the read clock data from the one or more combinational circuits based on the second clock frequency; and
a driver configured to:
obtain, from the first serialization component, the first portion of the read clock data;
obtain, from the second serialization component, the second portion of the read clock data; and
output, based on the first portion of the read clock data and the second portion of the read clock data, a read clock signal having a third clock frequency that is double the second clock frequency.

14. The system of claim 13, further comprising:
a synchronization signal generator configured to provide one or more synchronization signals to the one or more combinational circuits based on a synchronization parameter of the one or more control parameters, wherein the one or more synchronization signals cause the driver to initiate the read clock signal after a duration from a time at which a memory access command is obtained, the duration indicated by a duration parameter of the one or more control parameters.

15. The system of claim 13, further comprising:
a preamble signal generator configured to provide one or more preamble signals to the one or more combinational circuits, wherein the one or more preamble signals cause the driver to generate a preamble read clock signal prior to generating the read clock signal, wherein the preamble read clock signal has a fourth clock frequency that is equal to the second clock frequency.

16. The system of claim 15, wherein the preamble signal generator comprises a counter configured to obtain the second clock signal, and wherein the preamble signal generator is configured to modify the one or more preamble signals based on a value of the counter satisfying a threshold.

17. The system of claim 15, wherein the preamble read clock signal comprises a quantity of cycles, wherein the quantity of cycles is based on a quantity parameter of the one or more control parameters.

18. The system of claim 13, further comprising:
a third serialization component configured to obtain a third portion of the read clock data from the one or more combinational circuits based on the second clock signal;
a fourth serialization component configured to obtain a fourth portion of the read clock data from the one or more combinational circuits based on the second clock frequency; and
a second driver configured to:
obtain, based on the second clock signal, the third portion of the read clock data from the third serialization component;
obtain, based on the second clock signal, the fourth portion of the read clock data from the fourth serialization component; and
output a second read clock signal based on the third portion of the read clock data and the fourth portion of the read clock data.

19. A method, comprising:
receiving, by a memory apparatus comprising a synchronous graphics random access memory (SGRAM) associated with a first clock signal having a first clock frequency, a command to initiate a read clock;
generating, by the memory apparatus, read clock data based on one or more control parameters stored to a mode register and a second clock signal having a second clock frequency that is double the first clock frequency; and
outputting, by the memory apparatus, a read clock signal that is based on the read clock data, the read clock signal having a third clock frequency that is double the second clock frequency, wherein the read clock signal is associated with a memory access command for the SGRAM.

20. The method of claim 19, wherein generating the read clock data comprises:
providing the one or more control parameters to one or more combinational circuits; and
determining subsets of the read clock data via respective combinational circuits of the one or more combinational circuits, wherein the subsets of the read clock data are based on the one or more control parameters.

21. The method of claim 20, further comprising:
providing one or more synchronization signals to the one or more combinational circuits based on a synchronization parameter of the one or more control parameters, wherein determining the subsets of the read clock data is based on the one or more synchronization signals; and
transmitting, based on the one or more synchronization signals, the read clock signal after a duration from a time at which the command is obtained, the duration indicated by a duration parameter of the one or more control parameters, wherein transmitting the read clock signal is based on initiating the read clock signal.

22. The method of claim 20, further comprising:
providing one or more preamble signals to the one or more combinational circuits based on a preamble parameter of the one or more control parameters, wherein determining the subsets of the read clock data is based on the one or more preamble signals; and
transmitting, based on the one or more preamble signals, a preamble read clock signal prior to transmitting the read clock signal, wherein the preamble read clock signal has a fourth clock frequency that is half the third clock frequency.

23. The method of claim 19, further comprising:
receiving a second command to store the one or more control parameters to the mode register, wherein the second command comprises an indication of the one or more control parameters.

24. The method of claim 19, further comprising:
transmitting a second read clock signal based on the read clock data, wherein the second read clock signal is a complementary signal to the read clock signal, and wherein the read clock signal and the second read clock signal form a differential signal.
